(19) United States
(12) Patent Application Publication
(10) Pub. No.: US 2016/0349293 A1
(43) Pub. Date: Dec. 1, 2016

(54) APPARATUS AND METHOD FOR CONDITION MONITORING OF MULTIPLE ELECTRICAL SUB-SYSTEMS

(71) Applicant: Intel Corporation, Santa Clara, CA (US)

(72) Inventors: Rita Chattopadhyay, Chandler, AZ (US); Phillip M. Gurbacki, Scottsdale, AZ (US)

(21) Appl. No.: 14/724,325

(22) Filed: May 28, 2015

(51) Int. Cl. G01R 21/00; G01R 19/00; F24F 11/00

(52) U.S. Cl. CPC G01R 21/00; G01R 21/006; F24F 11/0086; G01R 19/0092; F24F 2011/0091; F24F 2011/0094

(57) ABSTRACT

Described is an apparatus which comprises: one or more sensors for coupling to a power source and for sensing electrical parameters of the power source, wherein the power source is operable to provide power to a system having one or more sub-systems; and a processor to analyze the sensed electrical parameters and to detect and identify one or more events associated with the system and the one or more sub-systems.

### BACKGROUND

Generally, electrical parameters such as current, voltage, power, power factor, etc. are measured at an input of an electrical system and the overall health of the electrical system is estimated based on these electrical parameters. Electrical systems may have many sub-systems or subunits. For example, a heating, ventilation, and air conditioning (HVAC) unit, consists of several sub-systems, such as compressor motors, fans, heaters, damper motors, etc. However, system level measurements do not allow for condition monitoring or anomaly detection at each of the subunit, component, or sub-system of the electrical system. Here, the terms “subunit,” “component,” and “sub-system” are interchangeably used. In order to monitor the health of these sub-systems, the electrical parameters for each of these subunits, components, or sub-systems have to be measured individually. However, it is not practically feasible to install electrical sensors and associated hardware for each of the sub-systems of an electrical system.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a system with an apparatus for condition monitoring of multiple electrical systems/sub-systems, according to some embodiments of the disclosure.

FIG. 2 illustrates the apparatus for condition monitoring of multiple electrical systems/sub-systems, according to some embodiments of the disclosure.

FIG. 3 illustrates a flowchart of a method for condition monitoring of multiple electrical systems/sub-systems, according to some embodiments of the disclosure.

FIG. 4 illustrates plots showing the performance of an Event Detector of the apparatus using three different inputs, according to some embodiments of the disclosure.

FIG. 5A illustrates a flowchart of a method for signal change detection, according to some embodiments of the disclosure.

FIG. 5B illustrates a series of plots associated with the method for signal change detection of FIG. 5A, according to some embodiments of the disclosure.

FIGS. 6A-B illustrate a series of plots showing the performance of the Event Detector, according to some embodiments.

FIGS. 7A-F illustrate a series of plots of signatures of various events based on current and power-factor, according to some embodiments.

FIG. 8 illustrates functional blocks for training phase and real-time usage of an Event Classifier, according to some embodiments of the disclosure.

FIG. 9 illustrates a plot showing event classifications based on Root Mean Square (RMS) current, according to some embodiments of the disclosure.

FIG. 10 illustrates a plot showing load disaggregation, according to some embodiments of the disclosure.

FIGS. 11A-B illustrate results of load disaggregation, according to some embodiments.

FIGS. 12A-B illustrate results of load disaggregation, according to some embodiments.

FIG. 13 illustrates a computing system for executing instructions for condition monitoring of multiple electrical systems/sub-systems, according to some embodiments.

### DETAILED DESCRIPTION

Various embodiments address the practical infeasibility to install electrical sensors for each of the sub-systems of an electrical system for monitoring conditions and health of the sub-systems. In some embodiments, an apparatus is provided which enables measurement of sub-system level electrical parameters such as power, average and peak current, power factor, etc., besides enabling observation of behavioral pattern of the sub-systems such as frequency of ON/OFF switching of sub-systems, duration of ON period of sub-systems, etc. In various embodiments, the condition monitoring and health check of the electrical sub-systems are based on the measurements at the upstream or at system level. As such, both system level and sub-system level condition monitoring is enabled for electrical units/systems.

In some embodiments, an apparatus is provided which comprises one or more sensors for coupling to a power source and for sensing electrical parameters of the power source, where the power source is operable to provide power to a system having one or more sub-systems. In some embodiments, the apparatus further comprises a processor to analyze the sensed electrical parameters and to detect and identify one or more events associated with the system and the one or more sub-systems.

Elements of embodiments are also provided as a machine-readable medium for storing the computer-executable instructions (e.g., instructions to implement any other processes discussed herein). The machine-readable medium may include, but is not limited to, flash memory, optical disks, Read Only Memories (ROMs) such as CD-ROMs, DVD ROMs, EPROMs, and EEPROMs, Random Access Memories (RAMs) such as Magnetic Random Access Memory (MRAM), magnetic or optical cards, Phase Change Memory (PCM), or other types of machine-readable media suitable for storing electronic or computer-executable instructions. For example, embodiments of the disclosure may be downloaded as a computer program (e.g., BIOS—Basic Input/Output System) which may be transferred from a remote computer (e.g., a server) to a requesting computer (e.g., a client) by way of data signals via a communication link (e.g., a modem or network connection).

In some embodiments, machine-readable media is provided having machine executable instructions that, when executed, cause one or more processors to perform an operation comprising of receiving of electrical parameters of a power source sensed by one or more sensors, where the power source is operable to provide power to a system having one or more sub-systems. In some embodiments, the operation further comprises detecting of one or more events associated with the system and the one or more sub-systems according to the sensed electrical parameters. In some embodiments, the operation further comprises identifying the one or more events associated with the system and the one or more sub-systems according to the sensed electrical parameters.

There are many technical effects of various embodiments. For example, some embodiments can perform condition monitoring of sub-systems based on the upstream electrical signals measured at the system level (e.g., without using additional downstream sensors for sub-systems). In some embodiments, an apparatus and method are provided which can detect both switching ON and OFF events of sub-systems based on changes in current signal(s). In some embodiments, an Event Classifier is provided as part of the apparatus and method, which is based on time domain features extracted from the average three phase current and power factor of the system input. In some embodiments, a method and apparatus are provided for Fault Detection and Identification (FDI) of a three phase electrical system based on time domain features extracted from two electrical signals. As such, the apparatus and method of various embodiments are computationally highly efficient.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct electrical, mechanical, or magnetic connection between the things that are connected, without any intermediary devices. The term “coupled” means either a direct electrical, mechanical, or magnetic connection between the things that are connected or an indirect connection through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The terms “substantially,” “close,” “approximately,” “near,” and “about,” generally refer to being within +/−20% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For purposes of the embodiments, the transistors in various circuits, modules, and logic blocks are metal oxide semiconductor (MOS) transistors, which include drain, source, gate, and bulk terminals. The transistors also include Tri-Gate and FinFET transistors, Gate All Around Cylindrical Transistors, Tunneling FET (TFET), Square Wire, or Rectangular Ribbon Transistors or other devices implementing transistor functionality like carbon nano tubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, eFET, etc., may be used without departing from the scope of the disclosure.

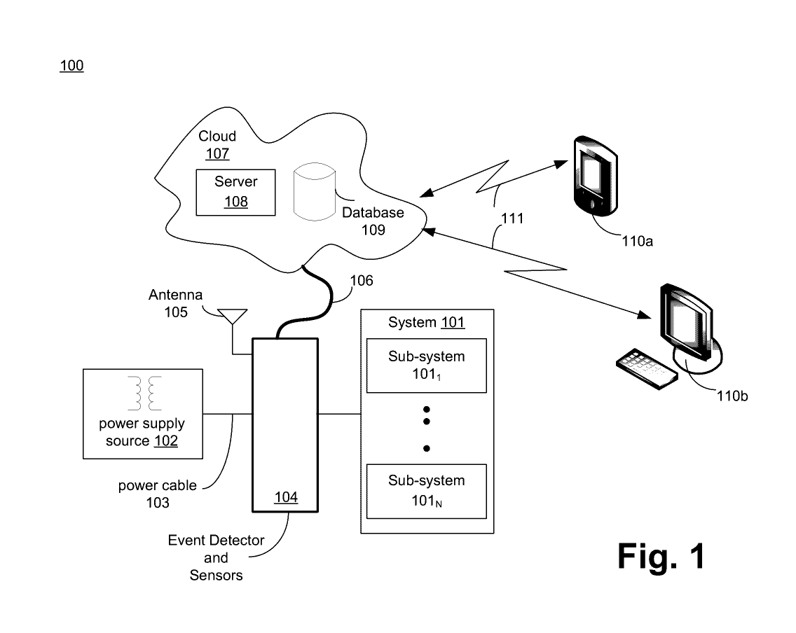

FIG. 1 illustrates system 100 with an apparatus for condition monitoring of multiple electrical systems/sub-systems, according to some embodiments of the disclosure. In some embodiments, system 100 comprises Electrical System 101, power supply source 102, power cable 103 (e.g., 3-phase power supply cable), Event Detector and Sensors 104, Antenna 105, connectivity 106, Cloud 107 having Server 108 and Database 109, and smart devices/computers 110a and 110b.

In some embodiments, Electrical System 101 comprises Sub-systems 101_{1-N}, where ‘N’ is an integer greater than one. For the purposes of explaining various embodiments, Electrical System 101 is assumed to be a heating, ventilation, and air conditioning (HVAC) unit (not shown), which comprises of several sub-systems 101_{1-N}, such as compressor motors (e.g., 101₁), fans (e.g., 101₂), heaters (e.g., 101₃), damper motors (e.g., 101₄), etc. However, the embodiments are not limited to monitoring of HVAC and its sub-systems, and various embodiments can be extended to monitor conditions of any electrical system and its sub-systems.

In some embodiments, a power supply source 102 provides a power source to Electrical System 101 via a power cable 103. For example, a 3-phase power supply is provided via power cable 103 to System 101. In some embodiments, Event Detector and Sensors 104 monitor various electrical parameters of the 3-phase power supply. In some embodiments, Sensors (here, part of 104) sense one or more electrical parameters such as voltage, current, power, and energy, etc. Any suitable sensors may be used implementing Sensors of block 104.

In some embodiments, output of the Sensors are sampled by an Event Detector (here, part of 104). In some embodiments, the Event Detector samples the output of the Sensors at a suitable sampling rate to capture multiple data samples during an event. As such, greater reliability and robustness of detection is achieved. Depending on the type of event being detected, different sensed electrical parameters are sampled.

For example, Compressor ON/OFF event is detected in voltage signals while the FAN ON event may not get detected with high accuracy using voltage signals because of noise on the voltage signals. In some embodiments, event detection method performed by the Event Detector can successfully detect the FAN ON and the COMPRESSOR ON/OFF events using raw Root-Mean-Square (RMS) current and active power signals, without any false alarms. The current or active power increases significantly after the compressor turns ON, hence, the detection of compressor ON/OFF activities are highly reliable. However, to capture the inrush current with 60 Hz sampling rate to detect a FAN ON event, a window length of a moving average is reduced for greater sensitivity to capture the event, in accordance with some embodiments. In some embodiments, sensor signals (i.e., output of Sensors) are sampled at a higher rate (e.g., 60 Hz or higher) in order to capture multiple data samples during an event.

In some embodiments, Antenna(s) 105 are provided as part of apparatus 104 to communicate with other devices (e.g., Cloud 107). In some embodiments, Antenna(s) 105 may comprise one or more directional or omnidirectional antennas, including monopole antennas, dipole antennas, loop antennas, patch antennas, microstrip antennas, coplanar wave antennas, or other types of antennas suitable for transmission of Radio Frequency (RF) signals. In some multiple-input multiple-output (MIMO) embodiments, Antenna(s) 105 are separated to take advantage of spatial diversity.

In some embodiments, connectivity 106 can include multiple different types of connectivity such as cables, cellular connectivity, and/or wireless connectivity. Cables refer generally to communication cables such as Ethernet cables. Cellular connectivity refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) generally refers to wireless connectivity that is not cellular, and can include personal area networks (such as Bluetooth, Near Field, etc.), local area networks (such as Wi-Fi), and/or wide area networks (such as WiMax), or other wireless communication.

In some embodiments, Cloud 107 includes Server 108 and Database 109. In some embodiments, Server 108 processes the output of Sensors and Event Detector 104, classifies the events and prepares reports and summaries for access by devices such as smart device 110a (e.g., a tablet) and desktop computer 110b via communication paths 111. The communication paths can be wired or wireless. In some embodiments, data from sensors and other building blocks are stored in Database 109 for processing purposes.

For example, large amount of data collected over time (i.e., data associated with electrical parameters of the 3-phase input, and other derived data such as power and current information of individual sub-systems) is stored in Database 109 to perform historical analysis of various activities of Electrical System 101 and its Sub-systems 101_{1-N}. In some embodiments, event detection takes place by Server 108. In one such embodiment, the output of Sensors (part of 104) are provided to Cloud 107 via Antenna 105 and/or connectivity 106 for processing (e.g., event detection, event classification, load disaggregation, heuristics/reports, etc.).

In some embodiments, whenever there is a switching ON or OFF event of an electrical sub-system (e.g., one of 101_{1-N}), the magnitude of the current and power factor changes at the upstream or system level (e.g., at power cable 103). In some embodiments, these changes are unique for a sub-system as each sub-system is characterized by its unique load impedance and characteristics (i.e., electrical signatures). In some embodiments, the changes to the magnitudes of the current and power factor are monitored by Event Detector and Sensors 104, and as such the operations of the sub-systems are detected and identified. This information is processed by Server 108 and provides a strong indicator of the health of each sub-system of Electrical System 101, in accordance with some embodiments.

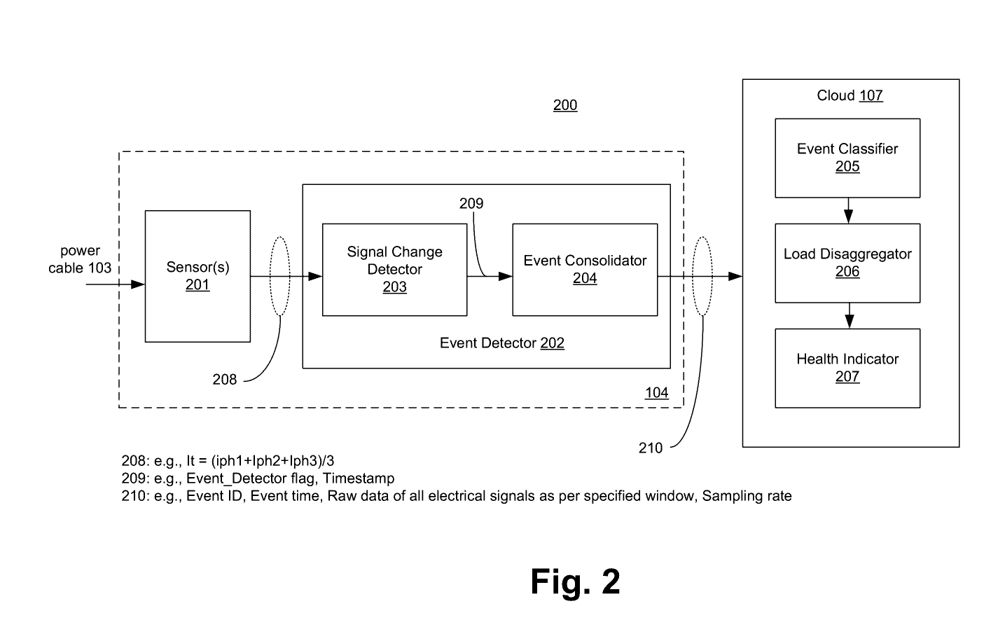

FIG. 2 illustrates apparatus 200 for condition monitoring of multiple electrical systems/sub-systems 101_{1-N}, according to some embodiments of the disclosure. It is pointed out that those elements of FIG. 2 having the same reference numbers (or names) as the elements of any other figure can operate or function in any manner similar to that described, but are not limited to such. In some embodiments, apparatus 200 is distributed between logic block 104 and Cloud 107. In some embodiments, apparatus 200 can be distributed in more components or can be consolidated in a single component.

In some embodiments, Sensor(s) 201 (e.g., voltage, current, energy sensors, etc.) receive the 3-phase power input from power cable 103 and generate phase currents (i.e., Iph1, Iph2, and Iph3) and their average “It” 208 (i.e., (Iph1+Iph2+Iph3)/3), where “Iph1” is the current for the first phase of the 3-phase power input, “Iph2” is the current for the second phase of the 3-phase power input, and “Iph3” is the current for the third phase of the 3-phase power input. In some embodiments, Event Detector 202 detects switching ON/OFF events of any electrical sub-system by detecting changes in average current “It” (i.e., average of the three phase currents) using a signal change detection method. In some embodiments, Event Detector 202 comprises Signal Change Detector 203 and Event Consolidator 204.

In some embodiments, Signal Change Detector 203 applies an offset based moving average method or scheme which is capable of detecting both sharp and gradual changes in the signal (e.g., the current signals of the three phases or the average current “It”). In some embodiments, the offset based moving average method computes a running average of a number of data samples which are apart from each other by an offset sample number. In some embodiments, the offset sample number is computed using an overlap percentage value (e.g., 10% of overlap). For example, Signal Change Detector 203 may use a window length of one second and an overlap percentage of 90%.

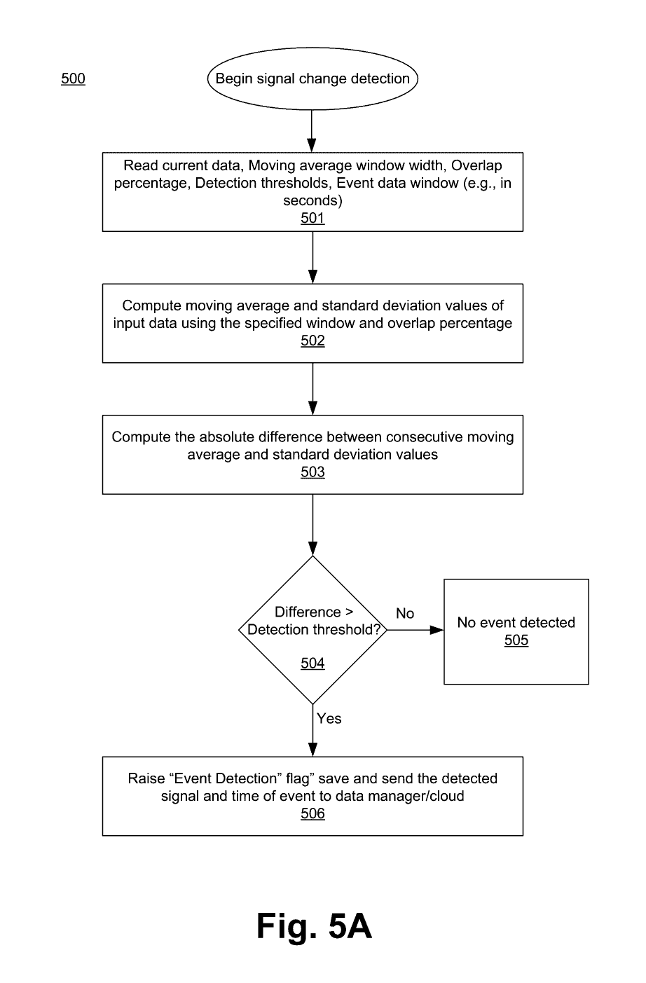

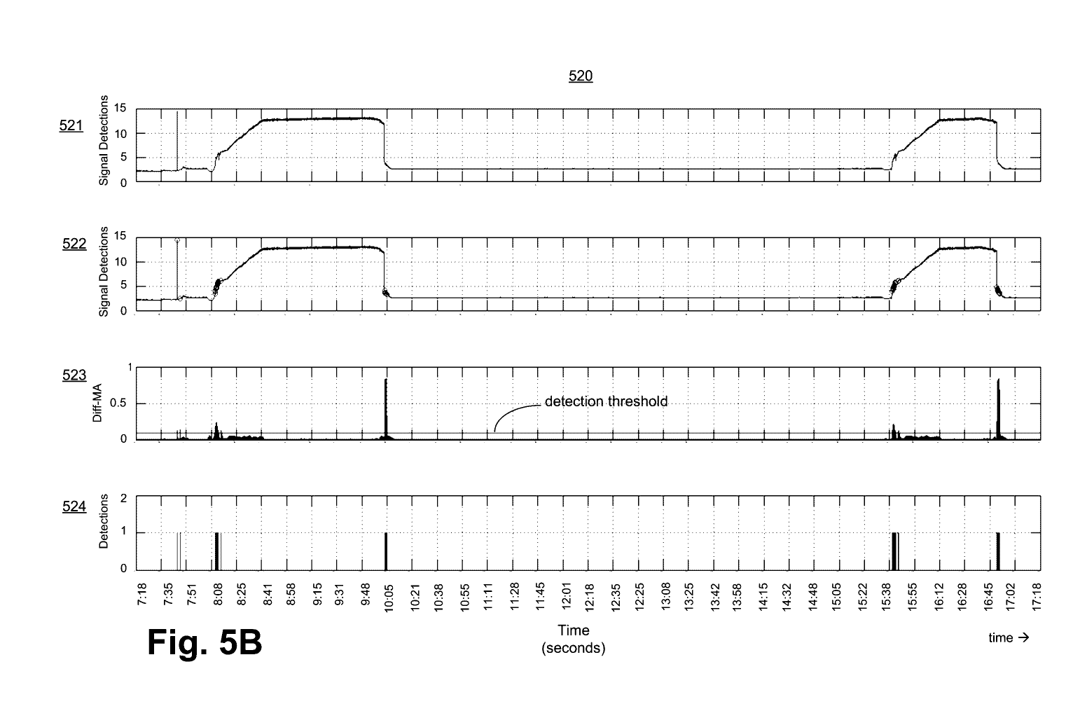

In some embodiments, Signal Change Detector 203 computes an absolute difference between consecutive moving average and standard deviation values. It then compares this absolute difference against a detector threshold (e.g., 0.1 Amperes). Depending on whether the absolute difference is above or below the detector threshold, a signal change or an event is detected by Signal Change Detector 203. In some embodiments, the output 209 of Signal Change Detector 203 is an “Event_Detection” flag/indicator and a timestamp associated with the detection of the event. One method of signal change detection performed by Signal Change Detector 203 and associated waveforms are described with reference to FIGS. 5A-B.

Referring back to FIG. 2, in some embodiments, Event Consolidator 204 receives output 209 of Signal Change Detector 203 and consolidates data over time. In some embodiments, Event Consolidator 204 combines multiple detections due to a single event into a single detection using a time based reference (i.e., once an event is detected, Event Detector 202 ignores all other detections within a specified time defined by configuration parameters). For example if an event is detected at time t1, then for 15 seconds, the Event Detector 202 may not report any other event. This time is configurable, and in this example it is set to 15 seconds based on empirical analysis. In some embodiments, Event Consolidator 204 generates data for each event that is detected by Signal Change Detector 203.

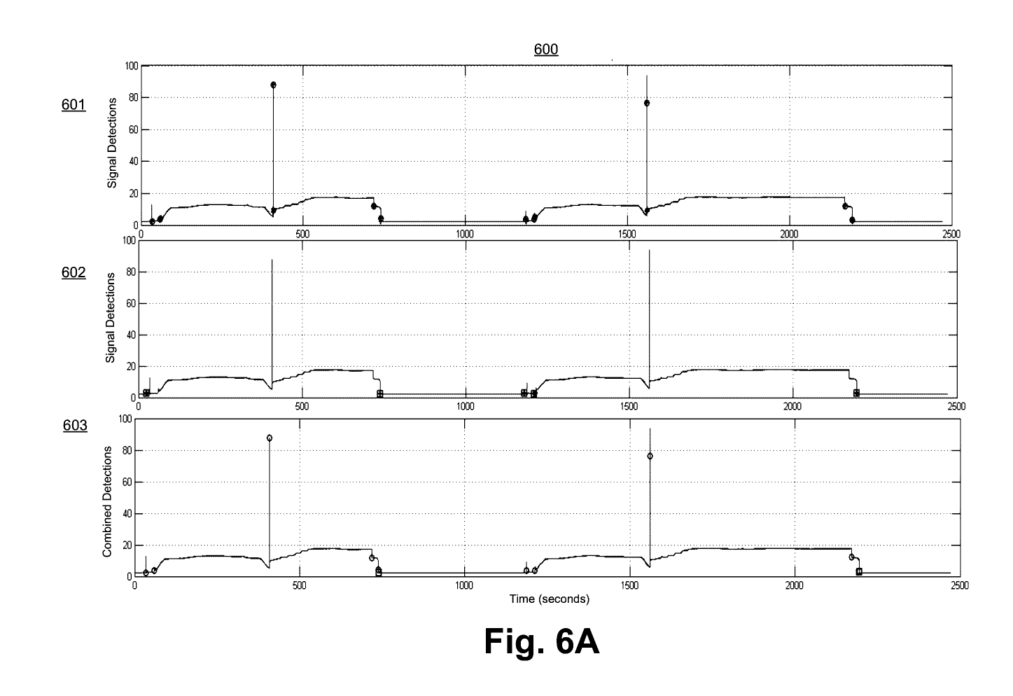

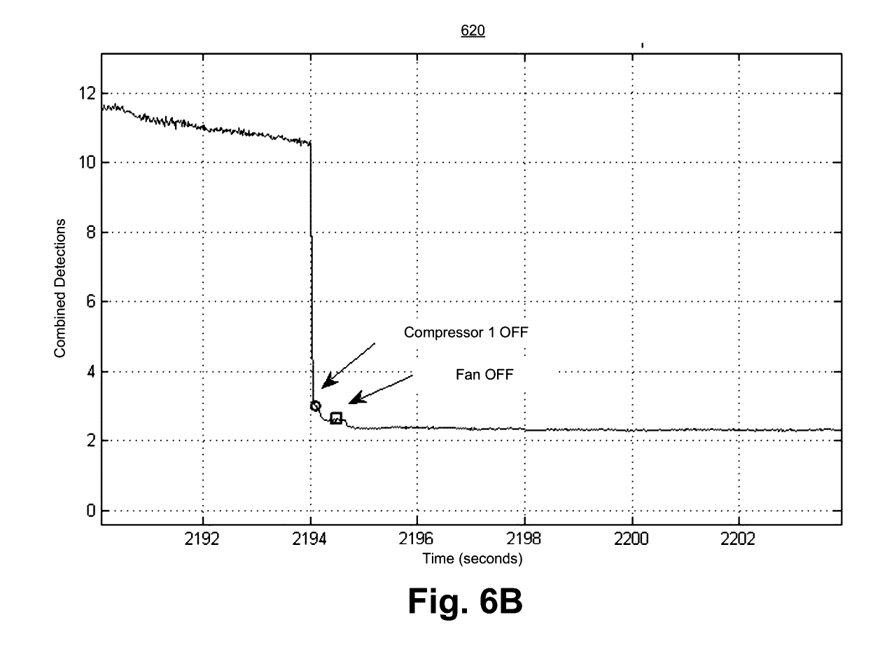

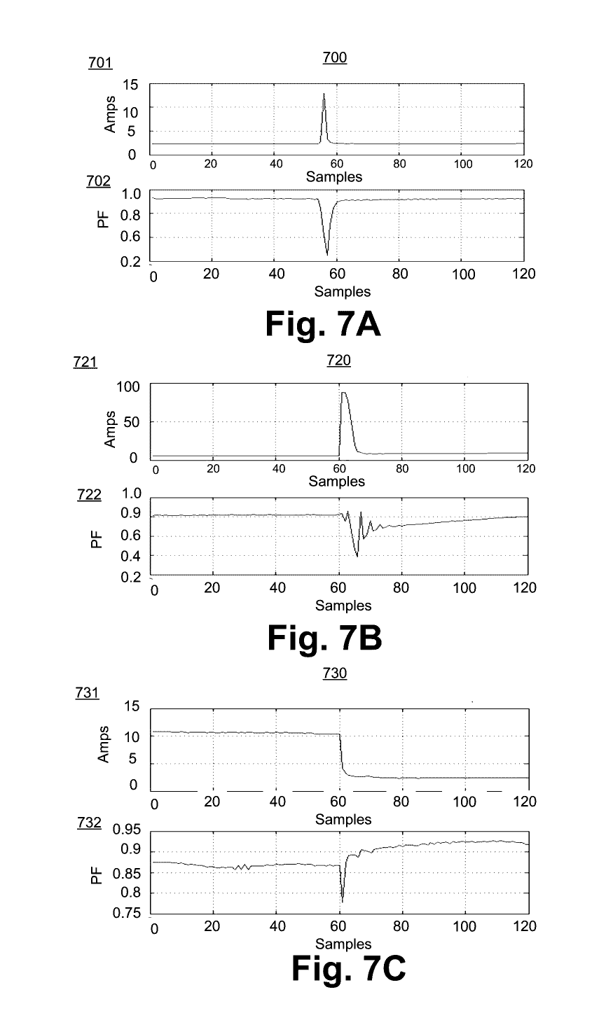

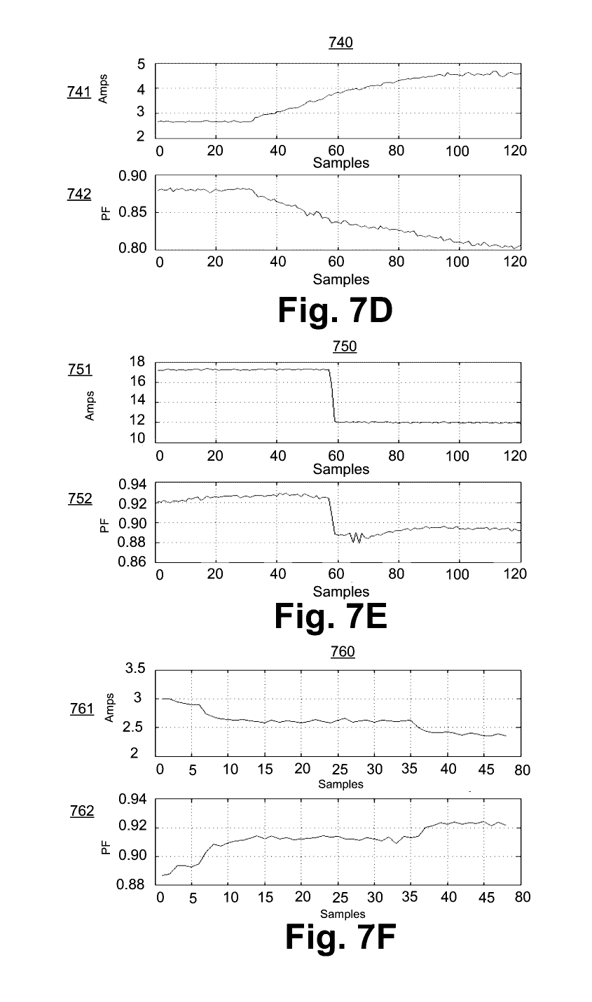

For example, Event Consolidator 204 generates an output 210 including Event ID (e.g., Compressor ON, FAN ON, etc.), Event time (e.g., time when the event occurred), raw data of all electrical signals as per specified window (e.g., V1, V2, V3, I1, I2, and I3 in a window of time which begins before the event and ends after the event by predetermined durations), and sampling rate (e.g., rate of sampling the data by Signal Change Detector 203). Performance of Event Detector 202 is illustrated by FIGS. 6A-B, according to some embodiments. Various signatures of identified events are illustrated with reference to FIGS. 7A-F, according to some embodiments.

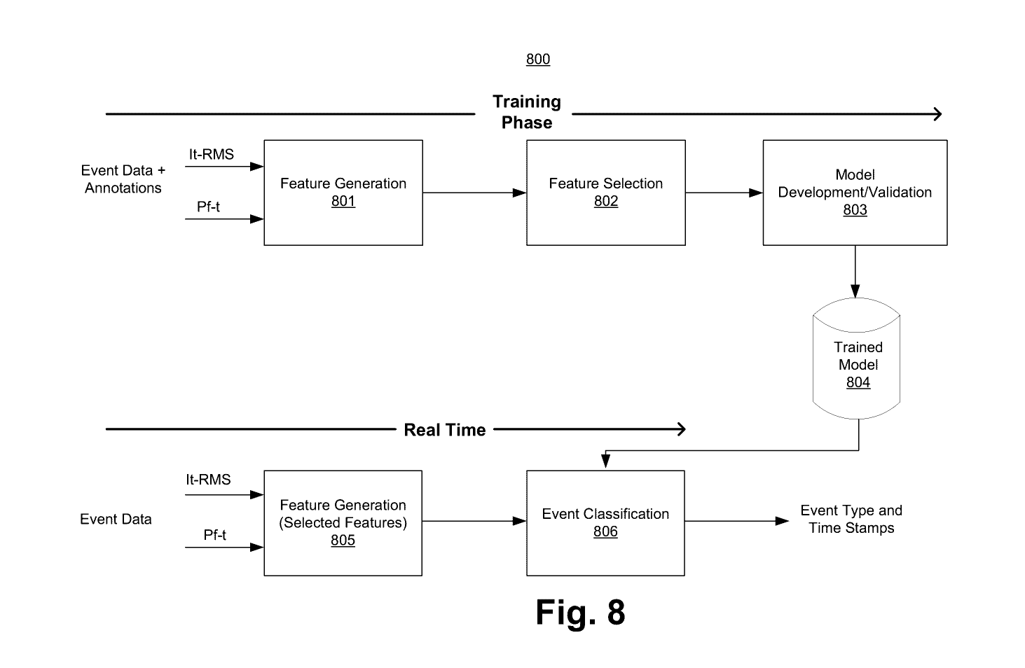

Referring back to FIG. 2, in some embodiments, output 210 is then transmitted via Antenna 105 and/or connectivity 106 to Cloud 107 for further processing. In some embodiments, Server 108 executes machine-readable instructions including instructions for Event Classifier 205, Load Disaggregator 206, and Health Indicator 207. In some embodiments, Event Classifier 205 identifies electrical events based on the signatures of average RMS current or peak-to-peak current and power factor data of Electrical System 101. In some embodiments, Event Classifier 205 identifies the ON/OFF condition of the sub-system associated with the detected event. In some embodiments, Event Classifier 205 uses machine learning tools (e.g., with training model(s)) to identify the ON/OFF condition of the sub-system. Machine learning tools explore the construction and study of algorithms that can learn from and make predictions on data (e.g., voltages, currents, power, power factors, etc.). Such algorithms operate by building a model (also referred to as a training model) from example inputs in order to make data-driven predictions or decisions, rather than following strictly static program instructions. A functional block diagram of Event Classifier 205 is described with reference to FIG. 8, according to some embodiments.

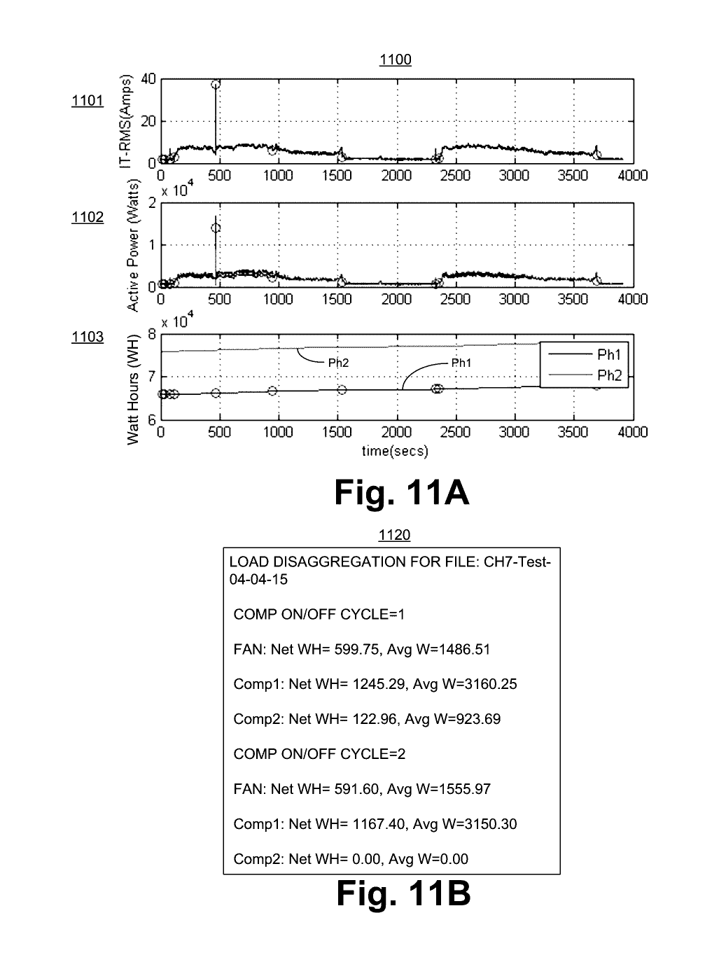

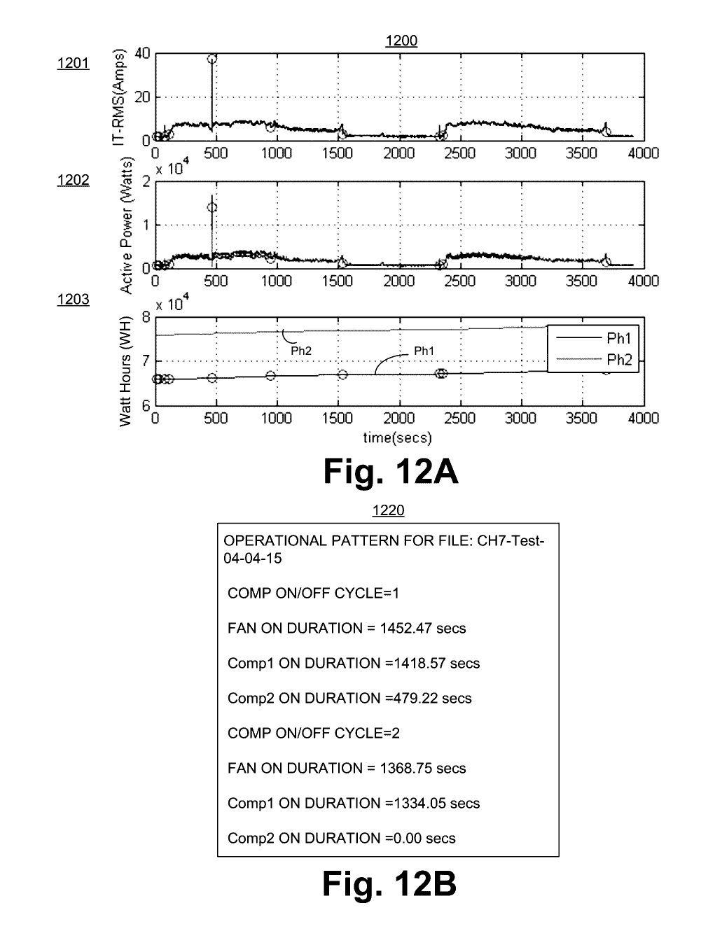

Referring back to FIG. 2, in some embodiments, Load Disaggregator 206 generates information regarding the operational pattern of the sub-systems including power consumption, average and peak current consumed by each sub-system, etc., based on the time of detected events and values of the electrical parameters during the ON periods of the sub-systems. In some embodiments, Load Disaggregator 206 generates component wise energy consumption and operational pattern of each component. FIGS. 11A-B and FIGS. 12A-B summarize results of Load Disaggregator 206, according to some embodiments.

Referring back to FIG. 2, in some embodiments, Health Indicator 207 generates a health status indicator or anomaly indicator based on the comparison with sub-system parameters under normal or healthy condition(s). Health status indicators can assist with taking necessary steps for proper and timely maintenance of Electrical System 101 and its Sub-systems 101_{1-N}. For example, a component of a compressor which is about to malfunction (based on the health status indicator) can be replaced before the component actually fails.

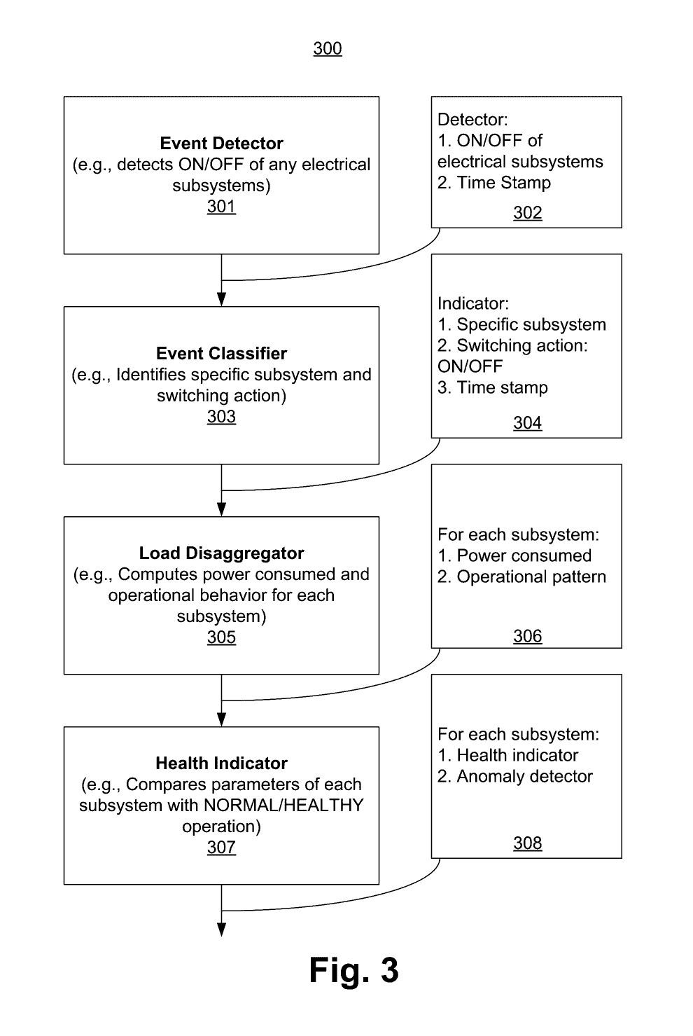

FIG. 3 illustrates flowchart 300 of a method for condition monitoring of multiple electrical systems/sub-systems, according to some embodiments of the disclosure. It is pointed out that those elements of FIG. 3 having the same reference numbers (or names) as the elements of any other figure can operate or function in any manner similar to that described, but are not limited to such.

Although the blocks in the flowchart with reference to FIG. 3 are shown in a particular order, the order of the actions can be modified. Thus, the illustrated embodiments can be performed in a different order, and some actions/blocks may be performed in parallel. Some of the blocks and/or operations listed in FIG. 3 are optional in accordance with certain embodiments. The numbering of the blocks presented is for the sake of clarity and is not intended to prescribe an order of operations in which the various blocks must occur. Additionally, operations from the various flows may be utilized in a variety of combinations.

At block 301, Event Detector 202 receives outputs of Sensor(s) and detects ON/OFF events of any of the electrical sub-systems 101_{1-N} along with configuration parameters. Examples of detected events include, ten FAN ON events, seven FAN OFF events, eleven Compressor 1 ON events, four Compressor 2 ON events, etc. These number of events for each type can be used for training a machine learning based training model, in accordance with some embodiments. In some embodiments, the configuration parameters include signals for event detection, moving average window length, overlap percentage, detection threshold, before event window, after event window, event detection gap. In some embodiments, values, numbers, and types of configuration parameters are adjusted to detect events. Different electrical systems may have different configuration parameters for detecting events of those electrical systems. In some embodiments, configuration parameters are programmable by hardware (e.g., fuse) or software (e.g., via operating system or other programs).

In some embodiments, Event Detector 202 monitors “It” (i.e., average of three phase currents sensed by Sensor(s)) using a signal change detection method. In some embodiments, output 302 of Event Detector 202 is a list of event detections of ON/OFF events of electrical sub-systems 101_{1-N}, their associated time stamps, sampling rate, and raw data of all electrical signals (e.g., RMS of “It” and average power factor) as per window (e.g., 1 second) specified by the configuration parameters.

At block 303, Event Classifier 205 receives output 302 of Event Detector 202 and identifies a specific sub-system and switching action (i.e., ON/OFF event) from the received output 302. In some embodiments, output 304 of Event Classifier 205 includes indications of what sub-system was involved in the event (e.g., sub-system name or identification (ID)), the switching action of the event (i.e., whether the sub-system turned ON or OFF), and associated time stamp of the event (e.g., when did the sub-system turn ON/OFF). In some embodiments, Event Classifier 205 has two phases—training and testing. In some embodiments, during the training phase, Event Classifier 205 generates time and frequency domain features and selects the most discriminative features using an automated method called RELIEF. In some embodiments, these features are then used to train a classification model. In some embodiments, during the testing phase, Event Classifier 205 extracts the selected features from the data and uses the pre-learned model to classify the event.

At block 305, Load Disaggregator 206 receives output 304 from Event Classifier and disaggregates performance and operational characteristics of each electrical sub-system. For example, Load Disaggregator 206 generates output 306 which includes computed power consumed, duration of the event, average operation duration, operational pattern, etc., for each sub-system.

At block 307, Health Indicator 207 performs analytics on the collected data (i.e., outputs 302, 304, and 306) and determines whether the sub-systems are operating normally. In some embodiments, Health Indicator 207 generates a health indicator and anomaly information 308 by comparing the collected data (or parameters) against predetermined thresholds. For example, if the sub-systems turn ON and OFF more than expected then an anomaly is indicated. In another example, if a sub-system remains OFF when it is supposed to turn ON, an indicator is flagged. In some embodiments, outputs 302, 304, 306, and 308 are accessible by computing devices 110a and 110b. In some embodiments, outputs 302, 304, 306, and 308 are stored in database 109 for use by Server 108 or other machines for other types of analysis such as historical analysis or performance of System 101.

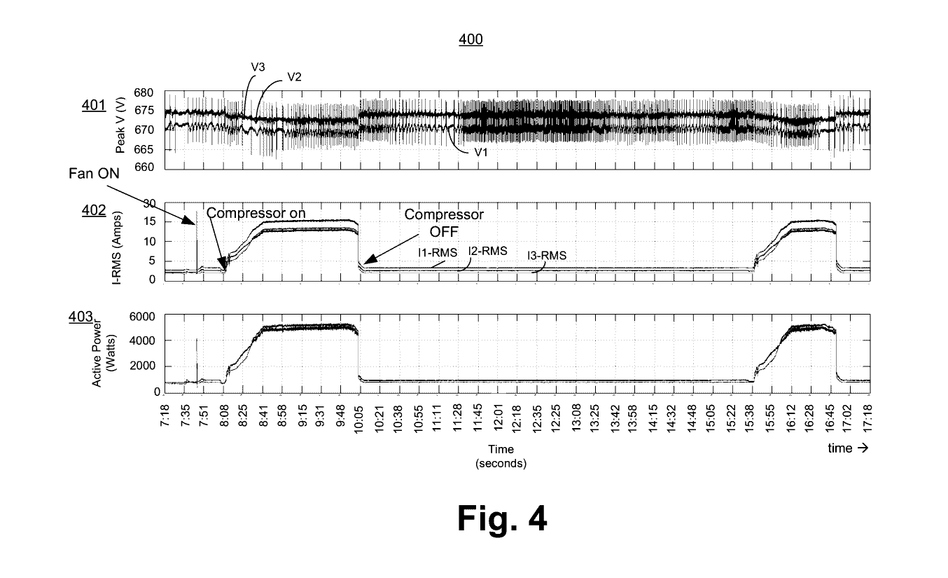

FIG. 4 illustrates a series of plots 400 showing the performance of Event Detector 202 using three different inputs, according to some embodiments of the disclosure. It is pointed out that those elements of FIG. 4 having the same reference numbers (or names) as the elements of any other figure can operate or function in any manner similar to that described, but are not limited to such.

Plot 401 shows peak voltages across time for the three phases—V1, V2, and V3. Here, x-axis is time and y-axis is peak voltage in Volts. Plot 402 shows the RMS currents (I-RMS) for the three phases (i.e., I1-RMS, I2-RMS, and I3-RMS). Here, x-axis is time and y-axis is I-RMS in Amperes (Amps). Plots 401 and 402 illustrate that for a HVAC system, it is more intuitive for Event Detector 202 to use I-RMS for detecting events than using the voltages for the 3-phases. However, for other electrical systems other electrical parameters may be more effective to detect and identify events.

Plot 402 illustrates the time points when a Fan turns ON, and when a Compressor turns ON and OFF. When the Fan turns ON, there is a sudden spike in I-RMS while when the Compressor turns ON, there is an initial spike followed by gradual rise in I-RMS. Likewise, when the Compressor turns OFF, there is a sudden I-RMS cliff. Plot 403 illustrates the active power for the three phases, where power is a product of voltage and current. Here, x-axis is time and y-axis is Active Power in Watts. In some embodiments, active power can also be used for detecting the events. However, the active power waveforms are slightly noisier because of the noise on the peak voltage. Depending on the electrical system, other electrical parameters may be more effective to detect and identify events.

FIG. 5A illustrates flowchart 500 of a method for signal change detection, according to some embodiments of the disclosure. It is pointed out that those elements of FIG. 5A having the same reference numbers (or names) as the elements of any other figure can operate or function in any manner similar to that described, but are not limited to such. FIG. 5B illustrates a series of plots 520 associated with the method for signal change detection of FIG. 5A, according to some embodiments of the disclosure. FIG. 5A is described with reference to FIG. 5B.

Although the blocks in the flowchart with reference to FIG. 5A are shown in a particular order, the order of the actions can be modified. Thus, the illustrated embodiments can be performed in a different order, and some actions/blocks may be performed in parallel. Some of the blocks and/or operations listed in FIG. 5A are optional in accordance with certain embodiments. The numbering of the blocks presented is for the sake of clarity and is not intended to prescribe an order of operations in which the various blocks must occur. Additionally, operations from the various flows may be utilized in a variety of combinations.

One aspect of Event Detector 202 is Signal Change Detector 203. At block 501, when Signal Change Detector 203 begins to operate, configuration parameters are read. For example, moving average window length or width (e.g., 1.0 second), minimum moving average event separation (e.g., 15 seconds), capture window size before event (e.g., 5 ms), capture window size after event (e.g., 5 ms), detection threshold in average RMS current (e.g., −1.0), detection threshold It-RMS for use in standard deviation based difference (e.g., −1.0), detection threshold for use in average based difference (e.g., 0.28), overlap percentage (e.g. 90%), etc. In some embodiments, the configuration parameters are programmable by hardware (e.g., fuse) or software (e.g., use of register via an operating system). In some embodiments, Signal Change Detector 203 also reads current data of the three phases from Sensor(s) 201. In some embodiments, Signal Change Detector 203 may read other data provided by Sensor(s) 201.

For example, Sensor(s) 201 may provide power data or voltages for the three phases. In some embodiments, Signal Change Detector 203 may use power data or voltages for the three phases to detect events associated with sub-systems 101_{1-N}. Plot 521 illustrates an example of raw current data. Here, x-axis is time and y-axis is current. In some embodiments, raw current data is input to Signal Change Detector 203. Plot 522 illustrates possible signal detections using the raw data. For example, the circles shown on the waveform of plot 522 are events detected by Signal Change Detector 203.

At block 502, Signal Change Detector 203 computes the moving average and standard deviation values of the current data (i.e., input data) using the configuration parameters such as moving average window width (e.g., 1 second) and overlap percentage (e.g., 90%). The moving average is a running average of a number of data samples (e.g., samples of I-RMS at 60 Hz) which are apart from each other by an offset sample number. The offset sample number is computed using the overlap percentage value. In this example, since the data is sampled at 60 Hz, the window length is 60 samples. At block 503, an absolute difference between consecutive (or subsequent) moving average and standard deviations values are computed.

At block 504, a determination is made regarding the absolute difference between consecutive (or subsequent) moving average and standard deviations values. If the absolute difference is greater than the detection threshold (e.g., 0.1 Amps) then the process proceeds to block 506, else the process proceeds to block 505. At block 505, Signal Change Detector 203 concludes that no event is detected from the input sensing data in view of the configuration parameters. In some embodiments, when no event is detected, no communication is triggered by Signal Change Detector 203 for processing by Cloud 107. At block 506, it is determined that an event is detected. In some embodiments, when an event is detected, Signal Change Detector 203 raises an Event Detection flag. Plot 523 illustrates an absolute difference between consecutive (or subsequent) moving average and standard deviations values. The horizontal line running across the x-axis is the detection threshold. Plot 524 illustrates the events which are the points in time where the absolute difference is greater than the detection threshold.

Upon detecting an event, data associated with the detected event is saved and sent to Cloud 107 for further processing. For example, data such as It-RMS, average power factor pf-t (e.g., pf-t=(pf_ph1+pf_ph2)/2, where “pf_ph1” is the power factor of phase 1 and “pf_ph2” is the power factor of phase 2), and specified window length (e.g., 1 second). In some embodiments, upon detecting an event, Event Consolidator 204 saves the data associated with the event along with other saved data regarding other detected events. In some embodiments, after Event Consolidator 204 has gathered information for a predetermined amount of time (e.g., 1 day, a month, six months, etc), then Event Consolidator 204 sends the saved consolidated data to Cloud 107 for further processing.

FIGS. 6A-B illustrate series of plots 600 and 620 showing the performance of Event Detector 202, according to some embodiments. It is pointed out that those elements of FIGS. 6A-B having the same reference numbers (or names) as the elements of any other figure can operate or function in any manner similar to that described, but are not limited to such. Plot 601 illustrates event detection (as shown by the circles on the waveform) by Event Detector 202. Plot 602 shows a repeat of the same events which are again detected correctly by Event Detector 202. Plot 603 shows a combination of plots 601 and 602. A zoomed version of a part of plot 603 is shown by plot 620 of FIG. 6B. In this example, signal pattern during Fan OFF event is shown.

FIGS. 7A-F illustrate a series of plots 700, 720, 730, 740, 750, and 760 showing the unique signatures of various events based on the current and power-factor, according to some embodiments. It is pointed out that those elements of FIGS. 7A-F having the same reference numbers (or names) as the elements of any other figure can operate or function in any manner similar to that described, but are not limited to such.

For each plot, two sub-plots are shown. The top sub-plot is It-RMS against time while the bottom sub-plot is power factor (PF) across number of samples. The signatures of various events depend on the type of event and the sub-system. In some embodiments, Event Detector 202 is operable to detect signature of events and then determine what kind of event it detected. In some embodiments, the signatures behave as a look-up table or a hash tag for Event Detector 202. The following plots are illustrated with reference to signatures of events associated with HVAC. However, other electrical systems and sub-systems may have different signatures.

Series of plots 700 show two signature plots 701 and 702, where plot 701 is the It-RMS while plot 702 is the power factor at the point of event detection of a Fan turning ON. Series of plots 720 show two signature plots 721 and 722, where plot 721 is the It-RMS while plot 722 is the power factor at the point of event detection of Compressor 2 turning ON. Series of plots 730 show two signature plots 731 and 732, where plot 731 is the It-RMS while plot 732 is the power factor at the point of event detection of Compressor 1 turning OFF. Series of plots 740 show two signature plots 741 and 742, where plot 741 is the It-RMS while plot 742 is the power factor at the point of event detection of Compressor 1 turning ON. Series of plots 750 show two signature plots 751 and 752, where plot 751 is the It-RMS while plot 752 is the power factor at the point of event detection of Compressor 2 turning OFF. Series of plots 760 show two signature plots 761 and 762, where plot 761 is the It-RMS while plot 762 is the power factor at the point of event detection of Fan turning OFF.

FIG. 8 illustrates functional blocks for training phase and real-time usage of an Event Classifier 800, according to some embodiments of the disclosure. It is pointed out that those elements of FIG. 8 having the same reference numbers (or names) as the elements of any other figure can operate or function in any manner similar to that described, but are not limited to such.

Although the blocks in FIG. 8 are shown in a particular order, the order of the actions can be modified. Thus, the illustrated embodiments can be performed in a different order, and some actions/blocks may be performed in parallel. Some of the blocks and/or operations listed in FIG. 8 are optional in accordance with certain embodiments. The numbering of the blocks presented is for the sake of clarity and is not intended to prescribe an order of operations in which the various blocks must occur. Additionally, operations from the various flows may be utilized in a variety of combinations.

In some embodiments, Event Classifier 800 comprises logics for Training Phase and Real Time execution. In some embodiments, the Training Phase comprises logics for Feature Generation 801, Feature Selection 802, and Model Development/Validation 803 to generate Trained Model 804. In some embodiments, during Training Phase, Event Data and Annotations are received and a training model is generated based on machine learning methods.

In some embodiments, logic for Feature Generation 801 generates features such as Standard Deviation, Mean, Root Mean Square, Maximum, Minimum, Differences between before and after event values, etc. In some embodiments, logic for Feature Selection 802 selects some or all features based on a selection criterion. In some embodiments, the selection method for selecting the features is RELIEF which is a feature selection algorithm used in binary classification. In other embodiments, other types of selection methods may be used. For example, chi-square (or hi-squared distribution), Info Gain, adaptive boosting (AdaBoost), etc. can be used for selecting the features.

In some embodiments, the selection criterion for RELIEF is time domain features with high discriminating power (i.e., features that can easily distinguish between events). For example, six time domain features from two signals (e.g., It-RMS and pf-t) may be used by Feature Selection block 802. For example, six features of mean, minimum, maximum, median, RMS and standard deviation are used for the two signals. In some embodiments, the selected features from Feature Selection 802 are used for developing Trained Model 804. In some embodiments, machine learning methods analyze the various signatures of the events, such as signatures of FIGS. 7A-F on It-RMS and power factor signals, to generate Trained Model 804.

Referring back to FIG. 8, in some embodiments, a supervised learning model such as Support Vector Machines (SVM) is used by Model Development/Validation block 803. In some embodiments, SVM is used to learn the non-linear boundaries (i.e., pre-trained model) between the features belonging to different electrical events. In some embodiments, the pre-trained model (i.e., Trained Model 804) is used is to identify electrical events at real time. In some embodiments, parameters of SVM model used for generating Trained Model 804 are linear kernel for kernel type, error penalty of one, and error tolerance of 0.001. In other embodiments, other parameters and values may be used for the SVM model. In some embodiments, Trained Model 804 is verified for accuracy to increase confidence in the classified events.

In some embodiments, Trained Model 804 is used during Real Time classification of detected events. In some embodiments, for Real Time classification of detected events, Event Classifier 800 comprises logics for Feature Generation 805 of selected features and Event Classification 806. The type and number of selected features may differ between electrical systems. For example, condition monitoring of HVAC may be different than condition monitoring of other electrical systems. As such, the type and number of selected features for HVAC may be different than the type and number of selected features for other electrical systems.

In some embodiments, Event Classifier 800 extracts a set of most discriminative time domain features (e.g., 6 features) from Event Data and user Training Model 804 (i.e., a pre-trained classification model) to identify the type of electrical event (i.e., one of the six electrical events or NO event). In some embodiments, output of Event Classification 806 are cycle number associated with each event (e.g., when the event occurred and when it occurred again), Event type (e.g., NO Event, Fan ON Event, Fan OFF Event, etc.), and Time Stamp of the event in seconds.

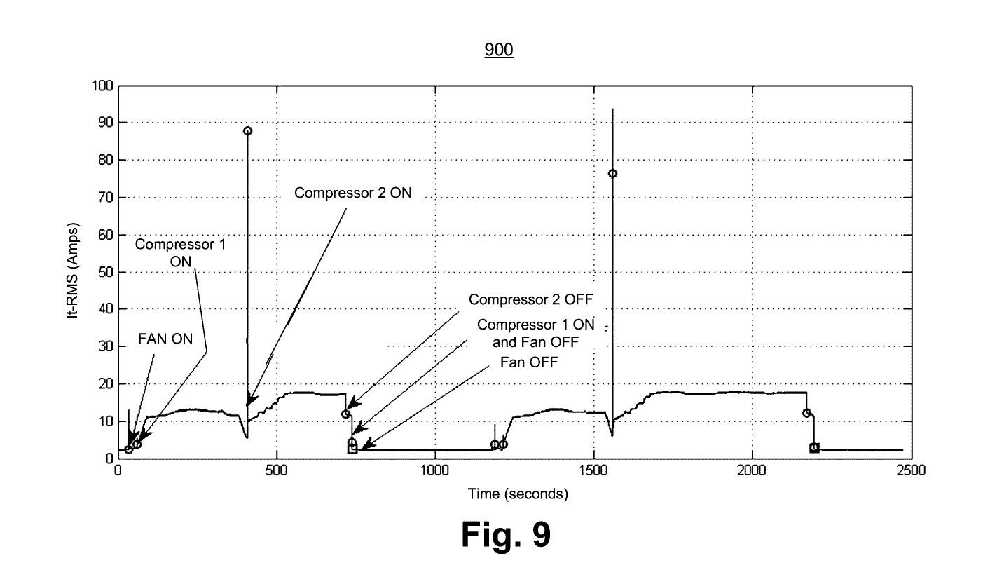

FIG. 9 illustrates plot 900 showing event classifications using Root Mean Square (RMS) current (i.e., It-RMS), according to some embodiments of the disclosure. It is pointed out that those elements of FIG. 9 having the same reference numbers (or names) as the elements of any other figure can operate or function in any manner similar to that described, but are not limited to such. Here, x-axis is time and y-axis is It-RMS in Amps.

Plot 900 is a visual illustration of operation of Event Classifier 800 for an HVAC system. Following the signatures of FIGS. 7A-F, Training Model 804 can distinguish between various events (e.g., Fan ON event, Compressor 1 ON event, Compressor 2 OFF event, etc.), in accordance to some embodiments.

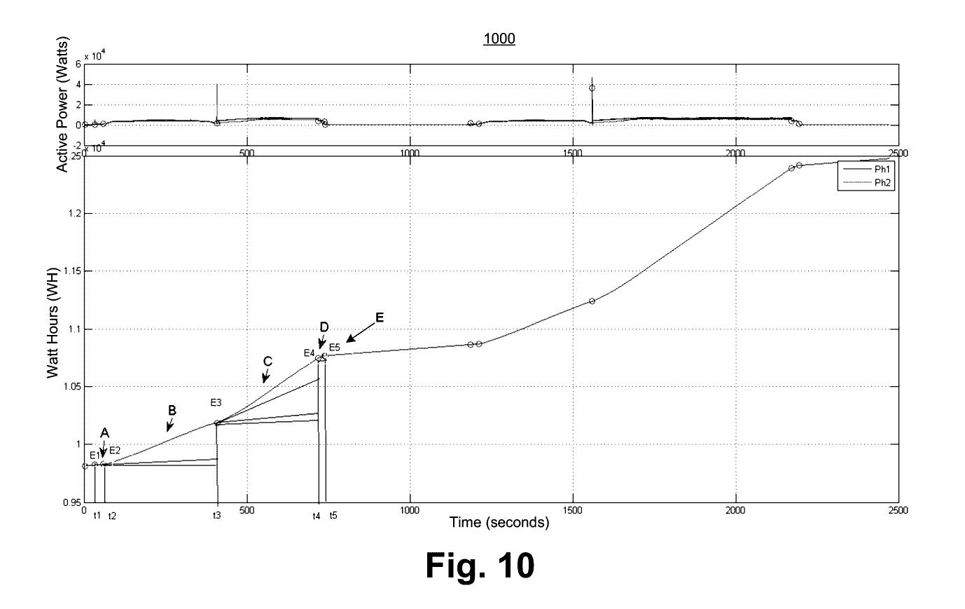

FIG. 10 illustrates plot 1000 showing load disaggregation, according to some embodiments of the disclosure. It is pointed out that those elements of FIG. 10 having the same reference numbers (or names) as the elements of any other figure can operate or function in any manner similar to that described, but are not limited to such.

In some embodiments, Load Disaggregator 206 computes power consumed and the operational behavior or pattern for each sub-system. So as not to obscure the embodiments, the operation of Load Disaggregator 206 is described according to the events illustrated in plot 1000. Plot 1000 includes two sets of waveforms. The first set of waveforms is on the top and illustrates active power (in Watts) across time. The second set of waveforms is below the first set of waveforms and illustrates Wattage Hour (WH) across the same time. Here, five events—A, B, C, D, and E—are illustrated. Some of the events occur in the presence of other events (i.e., overlapping events). In some embodiments, Load Disaggregator 206 can disaggregate the overlapping events and provides a report (e.g., power consumed, duration of event, type of event, etc.) on them.

In some embodiments, Load Disaggregator 206 computes the energy consumption (i.e., power) for each sub-system between a number of events. In this example, five events (A through E) are illustrated.

Load Disaggregator 206 identifies Event A which indicates Fan_A turning ON between Watt Hours E2 and E1, and a slope (Slope_Fan) of (E2−E1)(t2−t1), where t2 and t1 are time points. For Event A, Load Disaggregator 206 performs the following operations:
1. Fan_only_A=E2−E1
2. Slope_Fan=(E2−E1)/(t2−t1)

The next event is Event B. Load Disaggregator 206 then identifies Event B which overlaps with Event A. During Event B both Compressor 1 and Fan 1 are on (i.e., Fan_Comp1). Load Disaggregator 206 then determines the slopes for Compressor 1 and Fan 1. For Event B, Load Disaggregator 206 performs the following operations:
1. Fan_Comp1=E3−E2
2. Slope_Fan_Comp1=(E3−E2)/(t2−t1)
3. Fan_only_B=Slope_Fan*(t3−t2)
4. Comp1_only_B=Fan_Comp1−Fan_only_B

The next event is Event C. Load Disaggregator 206 then identifies Event C which overlaps with Events A and B. During Event C, Compressor 1, Compressor 2, and Fan 1 are on (i.e., Fan_Comp1_Comp2). For Event C, Load Disaggregator 206 performs the following operations:
1. Fan_Comp1_Comp2=E4−E3
2. Fan_Comp1=Slope_Fan_Comp1*(t4−t3)
3. Comp2_only_C=Fan_Comp1_Comp2−Fan_Comp1
4. Fan_only_C=Slope_Fan*(t4−t3)
5. Comp1_only_C=Fan_Comp1_Comp2−Comp2_only_C−Fan_only_C

The next event is Event D. Load Disaggregator 206 then identifies Event D which overlaps with Events A, B, and C. During Event D, Compressor 1, Compressor 2, and Fan 1 are on (i.e., Fan_Comp1_Comp2). For Event D, Load Disaggregator 206 performs the following operations:
1. Fan_Comp1=E5−E4
2. Fan_only_D=Slope_Fan*(t5−t4)
3. Comp1_only_D=Fan_Comp1−Fan_only_D

The next event is Event E. Load Disaggregator 206 then identifies Event E which overlaps with Events A, B, C, and D. For Event E, Load Disaggregator 206 performs the following operations:
1. Fan_only_E=E6−E5

Based on the operations for Events A, B, C, D, and E, Load Disaggregator 206 summarizes the data for the Fan, Compressor 1, and Compressor 2 for one Cycle starting from Fan ON event and ending with Compressor 1 OFF event as follows:
1. Fan_only=Fan_only_A+Fan_only_B+Fan_only_C+Fan_only_D+Fan_only_E
2. Comp1_only=Comp1_only_B+Comp1_only_C+Comp1_only_D
3. Comp2_only=Comp2_only_C

In some embodiments, Load Disaggregator 206 computes the operational parameters (e.g., time periods of an event, time gap between subsequent events, etc.) over a defined time period. For example, for each event, Load Disaggregator 206 determines a time period the sub-system is ON. This time period is equal to a difference of the time stamp when the sub-system is switched OFF and the time stamp when the sub-system is switched ON. In some embodiments, Load Disaggregator 206 also determines the time gap between subsequent switching ON time events, where time gap is the difference between the time stamp when the sub-system turned ON (i.e., t(n)) and the time stamp of a previous time instance when the sub-system turned ON (i.e., t(n−1)).

FIGS. 11A-B and FIGS. 12A-B illustrate results of Load Disaggregator 206, according to some embodiments. FIG. 11A illustrates a series of plots 1100 graphical representation of energy consumption (i.e., power). Here, the series 1100 shows three plots 1101 (It-RMS), 1102 (Active Power), and 1103 (Watt Hours) representing energy consumption per phase associated with a Sub-system and its events. The circles of the plots show the location in time of the events. FIG. 11B illustrates a text summary 1120 of the energy consumption, respectively, for sub-systems Fan, Compressor 1, and Compressor 2 using energy information at the upstream level (i.e., input of HVAC).

FIG. 12A illustrates a series of plots 1200 which are graphical representation of energy consumption (i.e., power). Here, the series 1200 shows three plots 1201 (It-RMS), 1202 (Active Power), and 1203 (Watt Hours) representing energy consumption per phase associated with a Sub-system and its events. The circles of the plots show the location in time of the events. FIG. 12B illustrates a text summary 1220 of the operational parameters, respectively, for sub-systems Fan, Compressor 1, and Compressor 2 using energy information at the upstream level (i.e., input of HVAC).

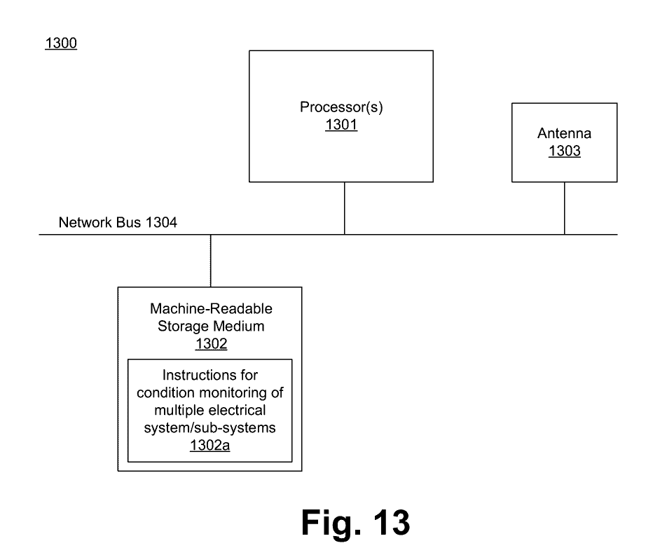

FIG. 13 illustrates a computing system 1300 for executing instructions for condition monitoring of multiple electrical systems/sub-systems. It is pointed out that those elements of FIG. 13 having the same reference numbers (or names) as the elements of any other figure can operate or function in any manner similar to that described, but are not limited to such.

In some embodiments, computing system 1300 comprises Processor(s) 1301 (e.g., a Digital Signal Processor (DSP), an Application Specific Integrated Circuit (ASCI), a general purpose Central Processing Unit (CPU) with single or multiple processor cores), Machine-Readable Storage Medium 1302 (also referred to as tangible machine readable medium), Antenna 1303 (e.g., Antenna 105) and Network Bus 1304. In some embodiments, the various logic blocks of computing system 1300 are coupled together via Network Bus 1304. Any suitable protocol may be used to implement Network Bus 1304. In some embodiments, Machine-Readable Storage Medium 1302 includes machine executable instructions 1302a (also referred to as the program software code/instructions) for condition monitoring of multiple electrical systems/sub-systems 101_{1-N} as described with reference to various embodiments and flowcharts.

Program software code/instructions 1302a associated with flowchart 300 and executed to implement embodiments of the disclosed subject matter may be implemented as part of an operating system or a specific application, component, program, object, module, routine, or other sequence of instructions or organization of sequences of instructions referred to as “program software code/instructions,” “operating system program software code/instructions,” “application program software code/instructions,” or simply “software” or firmware embedded in processor. In some embodiments, the program software code/instructions associated with flowchart 300 are executed by apparatus 104 and Cloud 107 (such as shown in FIGS. 1-2).

Referring back to FIG. 13, in some embodiments, the program software code/instructions 1302a associated with flowchart 300 are stored in a computer executable storage medium 1302 and executed by Processor 1301. Here, computer executable storage medium 1302 is a tangible machine readable medium that can be used to store program software code/instructions and data that, when executed by a computing device, causes one or more processors (e.g., Processor 1301) to perform a method(s) as may be recited in one or more accompanying claims directed to the disclosed subject matter.

The tangible machine readable medium 1302 may include storage of the executable software program code/instructions 1302a and data in various tangible locations, including for example ROM, volatile RAM, non-volatile memory and/or cache and/or other tangible memory as referenced in the present application. Portions of this program software code/instructions 1302a and/or data may be stored in any one of these storage and memory devices. Further, the program software code/instructions can be obtained from other storage, including, e.g., through centralized servers or peer to peer networks and the like, including the Internet. Different portions of the software program code/instructions and data can be obtained at different times and in different communication sessions or in the same communication session.

The software program code/instructions 1302a (associated with flowchart 300 and other embodiments) and data can be obtained in their entirety prior to the execution of a respective software program or application by the computing device. Alternatively, portions of the software program code/instructions 1302a and data can be obtained dynamically, e.g., just in time, when needed for execution. Alternatively, some combination of these ways of obtaining the software program code/instructions 1302a and data may occur, e.g., for different applications, components, programs, objects, modules, routines or other sequences of instructions or organization of sequences of instructions, by way of example. Thus, it is not required that the data and instructions be on a tangible machine readable medium in entirety at a particular instance of time.

Examples of tangible computer-readable media 1302 include but are not limited to recordable and non-recordable type media such as volatile and non-volatile memory devices, read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs), etc.), among others. The software program code/instructions 1302a may be temporarily stored in digital tangible communication links while implementing electrical, optical, acoustical or other forms of propagating signals, such as carrier waves, infrared signals, digital signals, etc. through such tangible communication links.

In general, tangible machine readable medium 1302 includes any tangible mechanism that provides (i.e., stores and/or transmits in digital form, e.g., data packets) information in a form accessible by a machine (i.e., a computing device), which may be included, e.g., in a communication device, a computing device, a network device, a personal digital assistant, a manufacturing tool, a mobile communication device, whether or not able to download and run applications and subsidized applications from the communication network, such as the Internet, e.g., an iPhone®, Galaxy®, Blackberry® Droid®, or the like, or any other device including a computing device. In one embodiment, processor-based system is in a form of or included within a PDA, a cellular phone, a notebook computer, a tablet, a game console, a set top box, an embedded system, a TV, a personal desktop computer, etc. Alternatively, the traditional communication applications and subsidized application(s) may be used in some embodiments of the disclosed subject matter.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. For example, other memory architectures e.g., Dynamic RAM (DRAM) may use the embodiments discussed. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

For example, an apparatus is provided which comprises: one or more sensors for coupling to a power source and for sensing electrical parameters of the power source, wherein the power source is operable to provide power to a system having one or more sub-systems; and a processor to analyze the sensed electrical parameters and to detect and identify one or more events associated with the system and the one or more sub-systems. In some embodiments, the processor to analyze the sensed electrical parameters according to configurable parameters associated with the system and its one or more sub-systems.

In some embodiments, the configurable parameters are at least one or more of: a moving average time window for detecting sharp and gradual changes to a signal; a percentage of overlap between the one or more events; or a detection threshold to detect the one or more events. In some embodiments, the processor is operable to compute a moving average and standard deviation of the sensed electrical parameters according to the configurable parameters, and wherein the computed moving average and standard deviation include consecutive moving average and standard deviation of the sensed electrical parameters.

In some embodiments, the processor is operable to: compute an absolute difference between the consecutive moving average and standard deviation of the sensed electrical parameters; compare the absolute difference against a detection threshold; and identify an event from among the one or more events according to the comparison. In some embodiments, the apparatus comprises a communication interface to communicate the identified event and associated data to another computing device, wherein the associated data includes at least one of: a time stamp; a type of the event; or a sub-system name of a sub-system, from among the one or more sub-systems, associated with the event.

In some embodiments, the other computing device to analyze the associated data and identified event and to determine a report having at least one of: information regarding operational pattern of the sub-system; power consumption of the sub-system; average current consumed by the sub-system; or peak current consumed by the sub-system. In some embodiments, the other computing device is operable to analyze the report and to generate an indicator indicating normal or abnormal operation of the sub-system. In some embodiments, the electrical parameters include at least one of: power of the system; average phase current of the system; or power factor of the system. In some embodiments, the system is a Heating Ventilation and Air Conditioning (HVAC) unit. In some embodiments, the one or more sub-systems of the HVAC unit include at least one of: compressor, fan, damper motor, or heater.

In another example, a machine-readable media is provided having machine executable instructions that, when executed, cause one or more processors to perform an operation comprising: receive electrical parameters of a power source sensed by one or more sensors, wherein the power source is operable to provide power to a system having one or more sub-systems; detect one or more events associated with the system and the one or more sub-systems according to the sensed electrical parameters; and identify the one or more events associated with the system and the one or more sub-systems according to the sensed electrical parameters.

In some embodiments, the machine-readable media has further machine executable instructions that, when executed, cause the one or more processors to perform a further operation comprising: analyze the sensed electrical parameters according to configurable parameters associated with the system and its one or more sub-systems. In some embodiments, the configurable parameters are at least one or more of: a moving average time window for detecting sharp and gradual changes to a signal; a percentage of overlap between the one or more events; or a detection threshold to detect the one or more events.

In some embodiments, the machine-readable media has further machine executable instructions that, when executed, cause the one or more processors to perform a further operation comprising: compute a moving average and standard deviation of the sensed electrical parameters according to the configurable parameters, and wherein the computed moving average and standard deviation include consecutive moving average and standard deviation of the sensed electrical parameters. In some embodiments, machine-readable media has further machine executable instructions that, when executed, cause the one or more processors to perform a further operation comprising: compute an absolute difference between the consecutive moving average and standard deviation of the sensed electrical parameters; compare the absolute difference against a detection threshold; and identify an event from among the one or more events according to the comparison.

In some embodiments, the machine-readable media has further machine executable instructions that, when executed, cause the one or more processors to perform a further operation comprising: communicate the identified event and associated data to another computing device, wherein the associated data includes at least one of: a time stamp; a type of the event; or a sub-system name of a sub-system, from among the one or more sub-systems, associated with the event.

In another example, a machine-readable media is provided having machine executable instructions that, when executed, cause one or more processors to perform an operation comprising: receive an identified event and data associated with electrical parameters of a power source sensed by one or more sensors, wherein the power source is operable to provide power to a system having one or more sub-systems; classify the identified event according to features including at least one of: standard deviation, mean, and root mean square; and analyze the associated data and classified event and to determine a report having at least one of: information regarding operational pattern of the sub-system; power consumption of the sub-system; average current consumed by the sub-system; or peak current consumed by the sub-system.

In some embodiments, the machine-readable media has further machine executable instructions that, when executed, cause the one or more processors to perform a further operation comprising: analyze the report and to generate an indicator indicating normal or abnormal operation of the sub-system. In some embodiments, the associated data includes at least one of: a time stamp; a type of the event; or a sub-system name of a sub-system, from among the one or more sub-systems, associated with the event.

In another example, a method comprising: receiving electrical parameters of a power source sensed by one or more sensors, wherein the power source is operable to provide power to a system having one or more sub-systems; detecting one or more events associated with the system and the one or more sub-systems according to the sensed electrical parameters; and identifying the one or more events associated with the system and the one or more sub-systems according to the sensed electrical parameters. In some embodiments, the method comprises analyzing the sensed electrical parameters according to configurable parameters associated with the system and its one or more sub-systems.

In some embodiments, the configurable parameters are at least one or more of: a moving average time window for detecting sharp and gradual changes to a signal; a percentage of overlap between the one or more events; or a detection threshold to detect the one or more events. In some embodiments, the method comprises: computing a moving average and standard deviation of the sensed electrical parameters according to the configurable parameters, and wherein the computed moving average and standard deviation include consecutive moving average and standard deviation of the sensed electrical parameters.

In some embodiments, the method comprises: computing an absolute difference between the consecutive moving average and standard deviation of the sensed electrical parameters; comparing the absolute difference against a detection threshold; and identifying an event from among the one or more events according to the comparison. In some embodiments, the method comprises: communicating the identified event and associated data to another computing device, wherein the associated data includes at least one of: a time stamp; a type of the event; or a sub-system name of a sub-system, from among the one or more sub-systems, associated with the event.

In another example, a method is provided which comprises: receiving an identified event and data associated with electrical parameters of a power source sensed by one or more sensors, wherein the power source is operable to provide power to a system having one or more sub-systems; classifying the identified event according to features including at least one of: standard deviation, mean, and root mean square; and analyzing the associated data and classified event and to determine a report having at least one of: information regarding operational pattern of the sub-system; power consumption of the sub-system; average current consumed by the sub-system; or peak current consumed by the sub-system.

In some embodiments, a method is provided which comprises: analyzing the report and to generate an indicator indicating normal or abnormal operation of the sub-system. In some embodiments, the associated data includes at least one of: a time stamp; a type of the event; or a sub-system name of a sub-system, from among the one or more sub-systems, associated with the event.

In another example, an apparatus is provided which comprises: means for receiving electrical parameters of a power source sensed by one or more sensors, wherein the power source is operable to provide power to a system having one or more sub-systems; means for detecting one or more events associated with the system and the one or more sub-systems according to the sensed electrical parameters; and means for identifying the one or more events associated with the system and the one or more sub-systems according to the sensed electrical parameters. In some embodiments, the apparatus comprises: means for analyzing the sensed electrical parameters according to configurable parameters associated with the system and its one or more sub-systems. In some embodiments, the configurable parameters are at least one or more of: a moving average time window for detecting sharp and gradual changes to a signal; a percentage of overlap between the one or more events; or a detection threshold to detect the one or more events.

In some embodiments, the apparatus comprises: means for computing a moving average and standard deviation of the sensed electrical parameters according to the configurable parameters, and wherein the computed moving average and standard deviation include consecutive moving average and standard deviation of the sensed electrical parameters. In some embodiments, the apparatus comprises: means for computing an absolute difference between the consecutive moving average and standard deviation of the sensed electrical parameters; means for comparing the absolute difference against a detection threshold; and means for identifying an event from among the one or more events according to the comparison. In some embodiments, the apparatus comprises: means for communicating the identified event and associated data to another computing device, wherein the associated data includes at least one of: a time stamp; a type of the event; or a sub-system name of a sub-system, from among the one or more sub-systems, associated with the event.

In another example, an apparatus is provided which comprises: means for receiving an identified event and data associated with electrical parameters of a power source sensed by one or more sensors, wherein the power source is operable to provide power to a system having one or more sub-systems; means for classifying the identified event according to features including at least one of: standard deviation, mean, and root mean square; and means for analyzing the associated data and classified event and to determine a report having at least one of: information regarding operational pattern of the sub-system; power consumption of the sub-system; average current consumed by the sub-system; or peak current consumed by the sub-system. In some embodiments, the apparatus comprises: means for analyzing the report and to generate an indicator indicating normal or abnormal operation of the sub-system. In some embodiments, the associated data includes at least one of: a time stamp; a type of the event; or a sub-system name of a sub-system, from among the one or more sub-systems, associated with the event.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. An apparatus comprising:
one or more sensors for coupling to a power source and for sensing electrical parameters of the power source, wherein the power source is operable to provide power to a system having one or more sub-systems; and
a processor to analyze the sensed electrical parameters and to detect and identify one or more events associated with the system and the one or more sub-systems.

2. The apparatus of claim 1, wherein the processor to analyze the sensed electrical parameters according to configurable parameters associated with the system and its one or more sub-systems.

3. The apparatus of claim 2, wherein the configurable parameters are at least one or more of:
a moving average time window for detecting sharp and gradual changes to a signal;
a percentage of overlap between the one or more events; or
a detection threshold to detect the one or more events.

4. The apparatus of claim 2, wherein the processor is operable to compute a moving average and standard deviation of the sensed electrical parameters according to the configurable parameters, and wherein the computed moving average and standard deviation include consecutive moving average and standard deviation of the sensed electrical parameters.

5. The apparatus of claim 4, wherein the processor is operable to:
compute an absolute difference between the consecutive moving average and standard deviation of the sensed electrical parameters;
compare the absolute difference against a detection threshold; and
identify an event from among the one or more events according to the comparison.

6. The apparatus of claim 5 comprises a communication interface to communicate the identified event and associated data to another computing device, wherein the associated data includes at least one of:
a time stamp;
a type of the event; or
a sub-system name of a sub-system, from among the one or more sub-systems, associated with the event.

7. The apparatus of claim 6, wherein the other computing device to analyze the associated data and identified event and to determine a report having at least one of:
information regarding operational pattern of the sub-system;
power consumption of the sub-system;
average current consumed by the sub-system; or
peak current consumed by the sub-system.

8. The apparatus of claim 7, wherein the other computing device is operable to analyze the report and to generate an indicator indicating normal or abnormal operation of the sub-system.

9. The apparatus of claim 1, wherein the electrical parameters include at least one of:
power of the system;
average phase current of the system; or
power factor of the system.

10. The apparatus of claim 1, wherein the system is a Heating Ventilation and Air Conditioning (HVAC) unit.

11. The apparatus of claim 10, wherein the one or more sub-systems of the HVAC unit include at least one of: compressor, fan, damper motor, or heater.

12. A machine-readable media is provided having machine executable instructions that, when executed, cause one or more processors to perform an operation comprising:
receive electrical parameters of a power source sensed by one or more sensors, wherein the power source is operable to provide power to a system having one or more sub-systems;
detect one or more events associated with the system and the one or more sub-systems according to the sensed electrical parameters; and
identify the one or more events associated with the system and the one or more sub-systems according to the sensed electrical parameters.

13. The machine-readable media of claim 12, having further machine executable instructions that, when executed, cause the one or more processors to perform a further operation comprising:
analyze the sensed electrical parameters according to configurable parameters associated with the system and its one or more sub-systems.

14. The machine-readable media of claim 13, wherein the configurable parameters are at least one or more of:
a moving average time window for detecting sharp and gradual changes to a signal;
a percentage of overlap between the one or more events; or
a detection threshold to detect the one or more events.

15. The machine-readable media of claim 14, having further machine executable instructions that, when executed, cause the one or more processors to perform a further operation comprising:
compute a moving average and standard deviation of the sensed electrical parameters according to the configurable parameters, and wherein the computed moving average and standard deviation include consecutive moving average and standard deviation of the sensed electrical parameters.

16. The machine-readable media of claim 15, having further machine executable instructions that, when executed, cause the one or more processors to perform a further operation comprising:
compute an absolute difference between the consecutive moving average and standard deviation of the sensed electrical parameters;
compare the absolute difference against a detection threshold; and
identify an event from among the one or more events according to the comparison.

17. The machine-readable media of claim 16, having further machine executable instructions that, when executed, cause the one or more processors to perform a further operation comprising:
communicate the identified event and associated data to another computing device, wherein the associated data includes at least one of:
a time stamp;
a type of the event; or
a sub-system name of a sub-system, from among the one or more sub-systems, associated with the event.

18. A machine-readable media is provided having machine executable instructions that, when executed, cause one or more processors to perform an operation comprising:
receive an identified event and data associated with electrical parameters of a power source sensed by one or more sensors, wherein the power source is operable to provide power to a system having one or more sub-systems;
classify the identified event according to features including at least one of: standard deviation, mean, and root mean square; and
analyze the associated data and classified event and to determine a report having at least one of:
information regarding operational pattern of the sub-system;
power consumption of the sub-system;
average current consumed by the sub-system; or
peak current consumed by the sub-system.

19. The machine-readable media of claim 18, having further machine executable instructions that, when executed, cause the one or more processors to perform a further operation comprising:
analyze the report and to generate an indicator indicating normal or abnormal operation of the sub-system.

20. The machine-readable media of claim 18, wherein the associated data includes at least one of:
a time stamp;
a type of the event; or
a sub-system name of a sub-system, from among the one or more sub-systems, associated with the event.
